(19) United States
(12) Patent Application Publication
(10) Pub. No.: US 2026/0045465 A1
(43) Pub. Date: Feb. 12, 2026

(54) PLASMA PROCESSING DEVICE AND ENDPOINT DETECTION METHOD

(71) Applicant: Tokyo Electron Limited, Tokyo (JP)

(72) Inventors: Chishio KOSHIMIZU, Miyagi (JP); Ryu NAGAI, Miyagi (JP)

(73) Assignee: Tokyo Electron Limited, Tokyo (JP)

(21) Appl. No.: 19/359,761

(22) Filed: Oct. 16, 2025

Related U.S. Application Data
(63) Continuation of application No. PCT/JP2024/014578, filed on Apr. 10, 2024.

(30) Foreign Application Priority Data
Apr. 25, 2023 (JP) 2023-071801

(51) Int. Cl. H01J 37/32

(52) U.S. Cl. CPC H01J 37/32972; H01J 37/32963; H01J 2237/332

(57) ABSTRACT

A plasma processing device includes: a spectrometer to measure luminous intensity during plasma processing; and a control circuitry to control etching endpoint detection based on measurement results on the spectrometer. When a layered film with first layers containing silicon and oxygen and second layers containing silicon and nitrogen is etched using plasma, the first and second layers stacked alternately on top of one another and forming the layered film together, the control circuitry: acquires first luminous intensity from the spectrometer, during plasma processing, from a first wavelength range of oxygen; acquires second luminous intensity from the spectrometer, during plasma processing, from a second wavelength range of nitrogen; and detects an etching endpoint in a first layer when the first luminous intensity decreases and the second luminous intensity increases, and detects an etching endpoint in a second layer when the second luminous intensity decreases and the first luminous intensity increases.

### CROSS-REFERENCE TO RELATED APPLICATIONS

This application is a continuation application of International Application No. PCT/JP2024/014578, filed on Apr. 10, 2024, and designated the U.S., which is based upon and claims the benefit of priority of prior Japanese Patent Application No. 2023-071801, filed on Apr. 25, 2023, the entire contents of each are incorporated herein by reference.

### BACKGROUND

### 1. Field

The present disclosure relates to a plasma processing device and an endpoint detection method.

### 2. Description of the Related Art

For example, Patent Document 1 discloses a method of etching silicon oxide (hereinafter also referred to as “CO”) and silicon nitride (hereinafter also referred to as “CN”) in a selective way. Patent Document 1 discloses finishing a step of etching silicon oxide when an end of silicon oxide etching is detected based on CO's luminous intensity. Patent Document 1 also discloses finishing a step of etching silicon nitride when an end of silicon nitride etching is detected based on CN's luminous intensity.

### CITATION LIST

### Patent Documents

Patent Document 1: Unexamined Japanese Patent Application Publication No. 2018-046185

### SUMMARY

According to one embodiment of the present disclosure, a plasma processing device is provided. This plasma processing device includes: a spectrometer configured to measure luminous intensity while plasma processing is in progress; and control circuitry configured to control etching endpoint detection based on measurement results gained on the spectrometer. When a layered film formed with first layers and second layers is etched using plasma, the first layers and the second layers being stacked alternately on top of one another and forming the layered film together, the first layers containing silicon and oxygen and the second layers containing silicon and nitrogen, the control circuitry is configured to:
(a) acquire a first luminous intensity from the spectrometer while plasma processing is in progress, the first luminous intensity being taken from a first wavelength range that is associated with the oxygen;
(b) acquire a second luminous intensity from the spectrometer while plasma processing is in progress, the second luminous intensity being taken from a second wavelength range that is different from the first wavelength range and associated with the nitrogen; and
(c) detect an etching endpoint in one of the first layers when the first luminous intensity shows a decrease and the second luminous intensity shows an increase, and detect an etching endpoint in one of the second layers when the second luminous intensity shows a decrease and the first luminous intensity shows an increase.

### BRIEF DESCRIPTION OF THE DRAWINGS

FIG. 1 is a diagram for explaining an example structure of a plasma processing system with a plasma processing device according to an embodiment of the present disclosure (hereinafter “the present embodiment”);

FIG. 2 is a flowchart for explaining the process carried out by the plasma processing device according to the present embodiment;

FIG. 3 is a diagram for explaining an overview of a layered film that is processed by the plasma processing device according to the present embodiment;

FIG. 4 is a diagram for explaining an overview of a layered film that is processed by the plasma processing device according to the present embodiment;

FIG. 5 is a diagram for explaining example emission spectra in the plasma processing device according to the present embodiment;

FIG. 6 is a diagram for explaining example emission spectra in the plasma processing device according to the present embodiment;

FIG. 7 is a diagram for explaining example emission spectra in the plasma processing device according to the present embodiment;

FIG. 8 is a diagram for explaining example emission spectra in the plasma processing device according to the present embodiment;

FIG. 9 is a diagram for explaining example emission spectra in the plasma processing device according to the present embodiment;

FIG. 10 is a diagram for explaining example emission spectra in the plasma processing device according to the present embodiment;

FIG. 11 is a diagram for explaining example emission spectra in the plasma processing device according to the present embodiment; and

FIG. 12 is a diagram for explaining example emission spectra in the plasma processing device according to the present embodiment.

### DETAILED DESCRIPTION OF THE PREFERRED EMBODIMENTS

The present disclosure provides a technique for efficiently detecting endpoints when etching a layered film formed with first layers and second layers that are stacked alternately on top of one another.

An embodiment for carrying out the present disclosure will be described below with reference to the accompanying drawings. Note that, throughout this specification and the drawings, the same or substantially the same components will be assigned the same or substantially the same reference numerals to avoid redundant description.

Furthermore, for ease of understanding, the scale of each part in the drawings may differ from the actual scale. Terms that indicate directions and orientations such as “parallel,” “right angles,” “orthogonal,” “horizontal,” “vertical,” “up,” “down,” “left,” “right,” and so forth may allow inaccuracies insofar as they do not impair the advantages that the present disclosure brings about. The shape of corners is not limited to right angles and may be rounded, for example. Parallel, right angles, orthogonal, horizontal, and vertical may include approximately parallel, approximately right angles, approximately orthogonal, approximately horizontal, and approximately vertical.

### <Plasma Processing System>

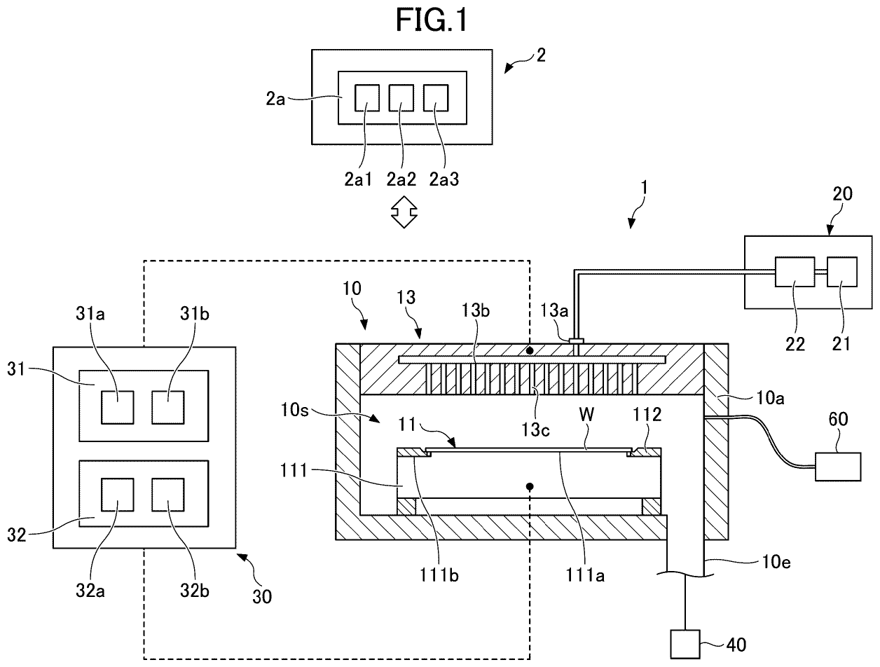

An example structure of a plasma processing system will be described below. FIG. 1 is a diagram illustrating an example structure of a plasma processing system including a plasma processing device 1, which is an example plasma processing device according to the present embodiment.

The plasma processing system includes the capacitively-coupled plasma processing device 1 and a control part 2. The capacitively-coupled plasma processing device 1 includes a plasma processing chamber 10, a gas supply part 20, a power supply part 30, a ventilation system 40, and a spectrometer 60. The plasma processing chamber 10 has at least one gas inlet for supplying at least one processing gas into a plasma processing space 10s, and at least one gas outlet for discharging the gas from the plasma processing space 10s. The plasma processing space 10s is in the plasma processing chamber 10. The plasma processing device 1 also has a substrate support part 11 and an upper electrode showerhead 13. The substrate support part 11 is positioned inside the plasma processing space 10s. The upper electrode showerhead 13 is positioned above the substrate support part 11 and forms at least a part of the ceiling of the plasma processing chamber 10.

The substrate support part 11 includes a main-body part 111 and an annular member (edge ring) 112. The main-body part 111 has a center part (substrate support surface) 111a for supporting a substrate (wafer) W and an annular part (edge ring support surface) 111b for supporting the annular member 112. The annular part 111b of the main-body part 111 surrounds the center part 111a of the main-body part 111. The substrate W is positioned on the center part 111a of the main-body part 111, and the annular member 112 is positioned over the annular part 111b of the main-body part 111 so as to surround the substrate W positioned in the center part 111a of the main-body part 111. According to one embodiment, the main-body part 111 includes a base and an electrostatic chuck. The base includes an electroconductive member (lower electrode). The electrostatic chuck is positioned on top of the base. The upper surface of the electrostatic chuck includes the substrate support surface 111a. Furthermore, although not shown in the drawings, according to one embodiment, the substrate support part 11 may include a temperature adjustment module that is configured to adjust at least one of the electrostatic chuck or the substrate to a target temperature. The temperature adjustment module may include a heater, a channel, or a combination of these. A temperature-control fluid such as a refrigerant or a heat transfer gas may flow in the channel.

The upper electrode showerhead 13 is configured to introduce at least one processing gas from the gas supply part 20 into the plasma processing space 10s. The upper electrode showerhead 13 has at least one gas inlet 13a, at least one gas diffusion chamber 13b, and multiple gas pipelines 13c. The processing gas supplied to the gas inlet 13a passes through the gas diffusion chamber 13b and is introduced into the plasma processing space 10s through the multiple gas pipelines 13c.

The gas supply part 20 may include at least one gas source 21 and at least one flow-rate controller 22. According to one embodiment, the gas supply part 20 is configured such that at least one processing gas is supplied to the upper electrode showerhead 13, from a corresponding gas source 21, through a corresponding flow-rate controller 22.

Each flow-rate controller 22 may include, for example, a mass-flow controller or a pressure-control-type flow rate controller. Furthermore, the gas supply part 20 may include one or more flow rate adjustment devices that modulate or pulse the flow rate of at least one processing gas.

The power supply part 30 includes an RF power supply part that is coupled to the plasma processing chamber 10. The RF power supply part is configured to supply at least one RF signal (RF power) such as a source RF signal, a bias RF signal, or the like, to the electroconductive member of the substrate support part 11 and/or to the upper electrode showerhead 13. Given this structure, plasma is generated from the processing gas supplied to the plasma processing space 10s. The RF power supply part can thus function as at least a part of a plasma generating part that is configured to generate plasma from one or more processing gases in the plasma processing chamber 10.

According to one embodiment, the RF power supply part includes a first RF generating part and a second RF generating part. The first RF generating part 31a is coupled to the electro-conductive member of the substrate support part 11 or the upper electrode showerhead 13, and configured to generate a source RF signal (source RF Power) for plasma generation. According to one embodiment, the source RF signal has a frequency ranging from 27 MHz to 100 MHz. The source RF signal generated thus is supplied to the electro-conductive member of the substrate support part 11 or to the upper electrode showerhead 13. The second RF generating part 31b is coupled to the electro-conductive member of the substrate support part 11 and configured to generate a bias RF signal (bias RF power). The bias RF signal generated thus is supplied to the electro-conductive member of the substrate support part 11. According to one embodiment, the bias RF signal has a lower frequency than the source RF signal. According to one embodiment, the bias RF signal has a frequency ranging from 400 kHz to 13.56 MHz. Furthermore, according to a variety of embodiments, the amplitude of at least one of the source RF signal or the bias RF signal may be modulated or pulsed. Amplitude modulation may include converting the amplitude of an RF signal between an “ON” mode and an “OFF” mode, or between two or more different “ON” modes.

Furthermore, the power supply part 30 may include a DC power supply part that is coupled to the plasma processing chamber 10. The DC power supply part includes a bias DC generating part. According to one embodiment, the bias DC generating part is connected to the electro-conductive member of the substrate support part 11 and configured to generate a bias DC signal. The generated bias DC signal is applied to the electro-conductive member of the substrate support part 11. According to one embodiment, the bias DC signal may be applied to another electrode, such as one provided in the electrostatic chuck. According to one embodiment, the bias DC signal may be pulsed. Furthermore, the bias DC generating part may be provided in addition to the RF power supply part, or may be provided instead of a second RF generating part.

The ventilation system 40 may be, for example, connected to a vent 10e formed in a bottom part of the plasma processing chamber 10. The ventilation system 40 may include a pressure valve and a vacuum pump. The vacuum pump may include a turbomolecular pump, a roughing pump, or a combination of these.

The spectrometer 60 detects the plasma emission spectra in the plasma processing space 10s. For example, the spectrometer 60 detects the luminous intensity in a wavelength range from 200 nanometers (hereinafter “nm”) to 900 nm. Note that the wavelength range in which the spectrometer 60 can detect luminous intensity is not limited to this example. For example, the spectrometer 60 may detect luminous intensities in a wavelength range from 200 nm to 1,100 nm.

The control part 2 processes computer-executable instructions that cause the plasma processing device 1 to perform various functions and steps described herein. The control part 2 may be configured to control each component of the plasma processing device 1 to perform various functions and steps described herein. According to one embodiment, the control part 2 may be partly or entirely included in the plasma processing device 1. The control part 2 may include, for example, a computer 2a. The computer 2a may include, for example, a processing part (central processing unit (CPU)) 2a1, a memory part 2a2, and a communication interface 2a3. The processing part 2al may be configured to perform various control operations based on programs stored in the memory part 2a2. The memory part 2a2 may include a random access memory (RAM), a read-only memory (ROM), a hard disk drive (HDD), a solid state drive (SSD), or a combination of these. The communication interface 2a3 may communicate with the plasma processing device 1 via a communication channel such as a local area network (LAN). The functionality of the elements disclosed herein may be implemented using circuitry or processing circuitry which includes general purpose processors, special purpose processors, integrated circuits, ASICS (“Application Specific Integrated Circuits”), FPGAS (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

Processing in the plasma processing device according to the present embodiment will be described. In describing the processing that the plasma processing device of the present embodiment carries out, the endpoint detection method that is executed by the plasma processing device of the present embodiment will be described.

For example, taking a 3-dimensional NAND flash memory as an example, unlike a conventional structure in which, for example, contacts of respective layers are provided in a stepped pattern, a structure in which contacts are provided using contact holes of varying depths has been proposed. That is, for example, if silicon dioxide film layers and silicon nitride film layers are stacked alternately on top of one another, etching must be ended in every silicon dioxide film layer and in every silicon nitride film layer. Therefore, it is important to detect an endpoint in every silicon dioxide film layer and silicon nitride film layer.

When etching a layered film formed with first layers and second layers being stacked alternately on top of one another, while the first layers are etched, less etchant is required, and the by-products produced from the first layers' etching increase. Likewise, while the second layers are etched, less etchant is required, and the by-products produced from the second layers' etching increase.

In other words, the present inventors have noticed that, when etching the first layers, the emission of light from the by-products produced from the etching of the first layers increases, and that, when etching the second layers, the emission of light from the by-products produced from the etching of the second layers increases, and thereupon arrived at the plasma processing device of the present embodiment. Furthermore, the present inventors have noticed that less etchant is required when etching the first layers and when etching the second layers, and arrived at the plasma processing device of the present embodiment.

When etching a layered film formed with first layers and second layers that are stacked alternately on top of one another, the plasma processing device of the present embodiment may detect respective luminous intensities in wavelength ranges associated with the by-products produced when the first layers are etched and in wavelength ranges associated with the by-products produced when the second layers are etched. Furthermore, based on these luminous intensities taken from wavelength ranges associated with the by-products produced during etching of the first layers and luminous intensities taken from wavelength ranges associated with the by-products produced during etching of the second layers, the plasma processing device of the present embodiment detects endpoints in the first layers and second layers. Furthermore, the plasma processing device of the present embodiment may detect the luminous intensity in a wavelength range that is associated with the etchant, and correct the luminous intensities determined by by-products.

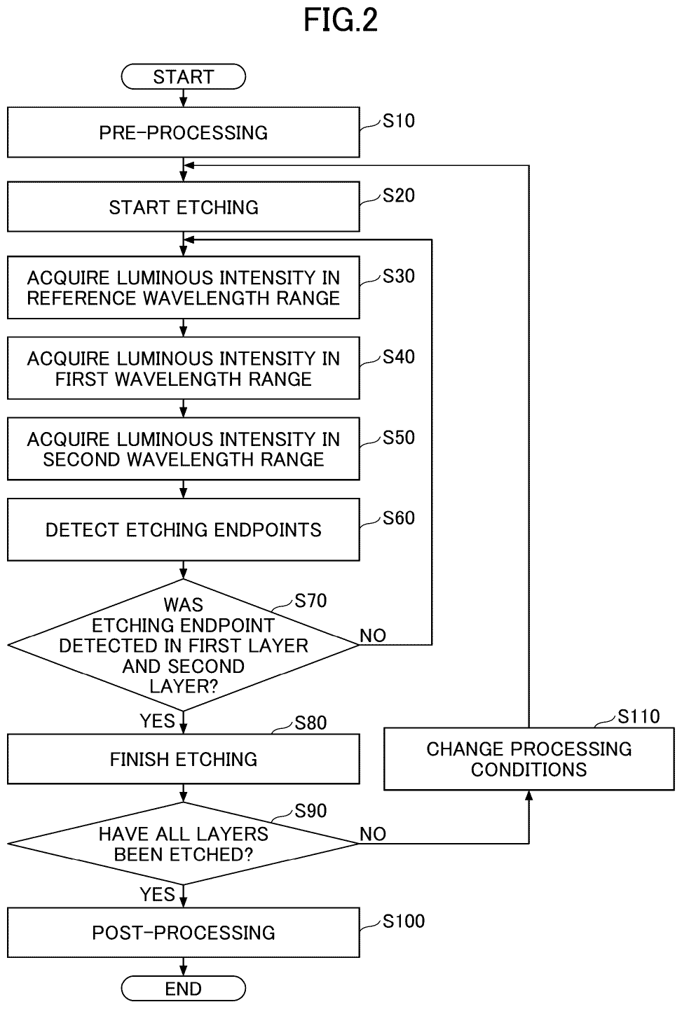

The plasma processing device 1, which is an example plasma processing device according to the present embodiment, will be described below. FIG. 2 is a flowchart for explaining the processing that the plasma processing device 1 carries out.

### (Step S10)

First, the control part 2 in the plasma processing device 1 performs a pre-processing step prior to etching. To be more specific, the control part 2 controls the loading of a wafer from outside. Then, the control part 2 controls the wafer such that the wafer is placed in the substrate support part 11.

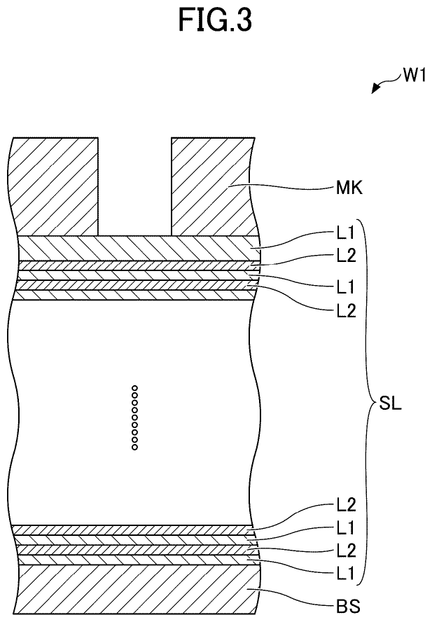

In the following description, a wafer W1 will be processed by the plasma processing device 1. FIG. 3 is a diagram for explaining an overview of a layered film SL that is processed by the plasma processing device 1.

The wafer W1 has a layered film SL on a substrate BS. The layered film SL is formed with first layers L1 and second layers L2 that are stacked alternately on top of one another. The first layers L1 are a silicon dioxide film containing silicon and oxygen. The second layers L2 are a silicon nitride film containing silicon and nitrogen. Furthermore, the wafer W1 has a mask MK on top of the layered film SL.

The plasma processing device 1 etches the part of the layered film SL where the mask MK is open. When etching the layered film SL, the plasma processing device 1 etches a first layer L1 and then etches a second layer L2, alternately.

### (Step S20)

Next, the control part 2 begins the etching. Because the wafer W1 has a first layer L1 directly underneath the mask MK, the control part 2 sets the processing gas, temperature, and other conditions to be suitable for etching of the first layers L1, and starts the process by generating plasma.

In the plasma processing device 1, a hydrogen fluoride gas (HF) is used as the processing gas when etching the first layers L1 and the second layers L2. The flow rate of the hydrogen fluoride gas in the processing gas may be 70 vol % or higher.

Note that, in addition to the hydrogen fluoride gas, for example, at least one of: a carbon-containing gas; an oxygen-containing gas; or at least one gas selected from the group consisting of a halogen-containing gas and a phosphorus-containing gas, may be used as a processing gas.

The carbon-containing gas may be at least one gas selected from the group consisting of a fluorocarbon gas, a hydrofluorocarbon gas, and a hydrocarbon gas.

### (Step S30)

Next, from the spectrometer 60, the control part 2 acquires reference luminous intensities from reference wavelength ranges that are associated with the etchant. For the etchant, the plasma processing device 1 uses hydrogen fluoride. Since hydrogen fluoride is used as the etchant, the control part 2 acquires luminous intensities from wavelength ranges that are associated with hydrogen and fluorine, which are contained in the etchant.

To take a luminous intensity from a wavelength range, the control part 2 may take the highest luminous intensity among the wavelengths included in the wavelength range, or determine the average or sum value of the respective luminous intensities of the wavelengths included in the wavelength range. The same applies hereinafter whenever a luminous intensity is taken from a wavelength range.

For example, at least one of a wavelength range including 483 nm or a wavelength range including 656 nm may serve as an example wavelength range associated with hydrogen. To be more specific, an example wavelength range associated with hydrogen may be, for example, one that includes a spectral line of the Balmer series of hydrogen atoms, which is at least one wavelength among, for example, 656.3 nm, 486.1 nm, 434.1 nm, 410.2 nm, and 397.0 nm. Likewise, at least one of a wavelength range including 704 nm or a wavelength range including 713 nm may serve as an example wavelength range associated with fluorine. To be more specific, an example wavelength range associated with fluorine may be, for example, one that includes a spectral line of fluorine atoms, which is at least one wavelength among 720.2 nm, 712.8 nm, 703.7 nm, 696.6 nm, 691.0 nm, 690.2 nm, and 685.6 nm.

### (Step S40)

Next, the control part 2 may acquire a first luminous intensity from the spectrometer 60, which is the luminous intensity in a first wavelength range that is associated with the oxygen. The first layers L1 may contain silicon and oxygen. Therefore, while the first layers L1 are being etched, the emission of light due to atoms, molecules, or ions originating from the oxygen contained in the first layers L1 is expected to increase. Therefore, the control part 2 acquires a luminous intensity from a wavelength range associated with oxygen.

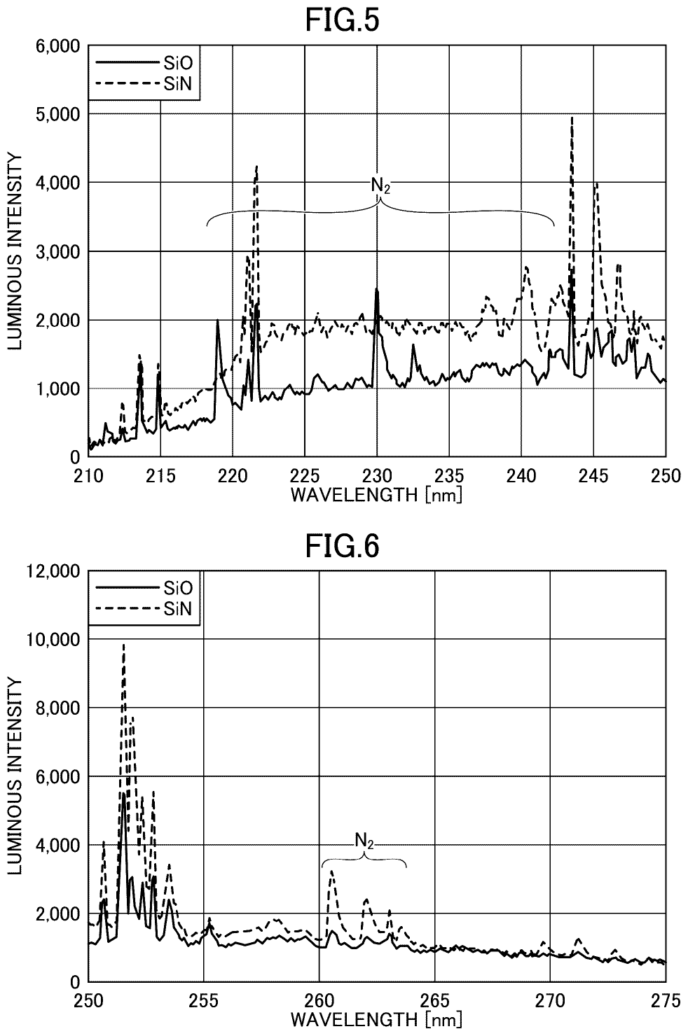

How the plasma processing device 1 acquires luminous intensity measurement results will be described below. FIG. 5 to FIG. 12 are diagrams for explaining example emission spectra measured by the plasma processing device 1.

The horizontal axis in FIG. 5 to FIG. 12 is wavelength (unit of measurement: nm). The vertical axis in FIG. 5 to FIG. 12 is the luminous intensity detected (unit of measurement: unspecified). In FIG. 5 to FIG. 12, the solid line is the luminous intensity observed while a silicon oxide film is etched, and the dotted line is the luminous intensity observed while a silicon nitride film is etched.

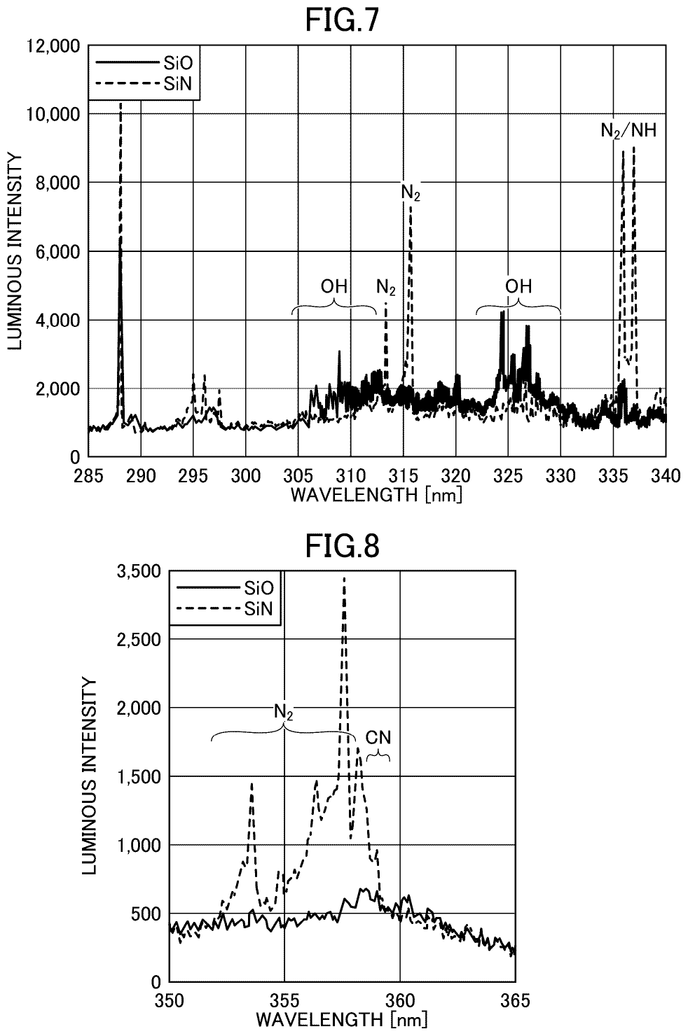

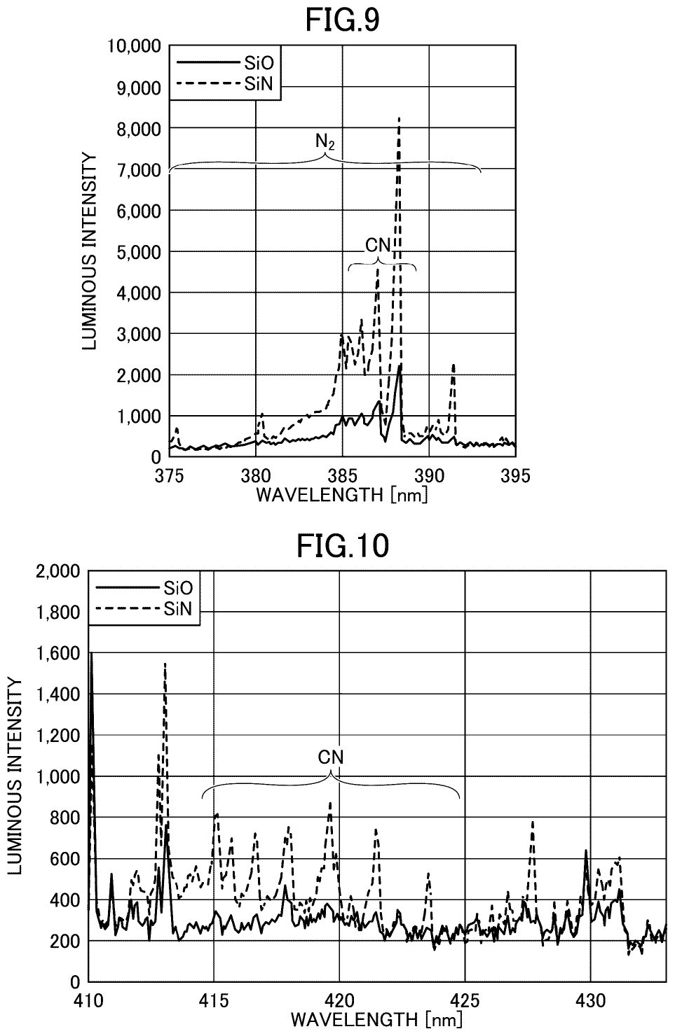

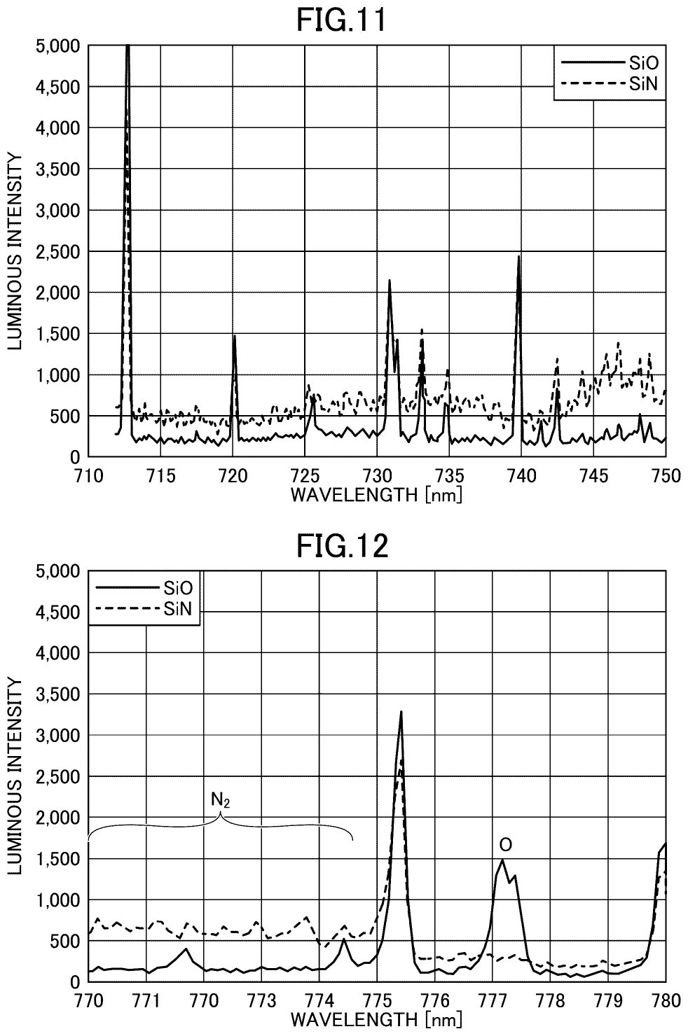

FIG. 5 shows the results in a wavelength range from 210 nm to 250 nm. FIG. 6 shows the results in a wavelength range from 250 nm to 275 nm. FIG. 7 shows the results in a wavelength range from 285 nm to 340 nm. FIG. 8 shows the results in a wavelength range from 350 nm to 365 nm. FIG. 9 shows the results in a wavelength range from 375 nm to 395 nm. FIG. 10 shows the results in a wavelength range from 410 nm to 433 nm. FIG. 11 shows the results in a wavelength range from 710 nm to 750 nm. FIG. 12 shows the results in a wavelength range from 770 nm to 780 nm.

According to the plasma processing device of the present embodiment, when the silicon oxide film and the silicon nitride film are etched, the difference between the two films in luminous intensity is significant, and a wavelength range in which high luminous intensity is observed when the silicon oxide film is etched is used as a first wavelength range. Note that, for the first wavelength range, one wavelength range or multiple wavelength ranges may be chosen from among the following wavelength ranges.

For example, example wavelength ranges associated with oxygen may include one that is associated with oxygen atoms (O) and one that is associated with hydroxyl radicals (OH). For example, at least one of a wavelength range including 777 nm (see FIG. 12) or a wavelength range including 844 nm may serve as an example wavelength range associated with oxygen atoms. To be more specific, a wavelength range including a spectral line of oxygen atoms, that is, a wavelength range including at least one of, for example, 777.2 nm, 777.4 nm, 794.8 nm, or 844.6 nm, may serve as another example wavelength range associated with oxygen atoms. For example, at least one of a wavelength range including 309 nm (see FIG. 7) or a wavelength range including 324 nm (see FIG. 7) may serve as an example wavelength range associated with hydroxyl radicals. To be more specific, for example, at least one of a wavelength range from 306 nm to 313 nm, including 308.9 nm, or a wavelength range from 323 nm to 328 nm may serve another example wavelength range associated with hydroxyl radicals.

### (Step S50)

Next, the control part 2 may acquire a second luminous intensity from the spectrometer 60, which is the luminous intensity in a second wavelength range that is associated with nitrogen. The second layers L2 may contain silicon and nitrogen. Therefore, while the second layers L2 are being etched, the emission of light from the atoms, molecules, or ions of the nitrogen contained in the second layers L2 is likely to increase. Therefore, the control part 2 acquires a luminous intensity from a wavelength range associated with nitrogen.

According to the plasma processing device of the present embodiment, when the silicon oxide film and the silicon nitride film are etched, the difference between the two films in luminous intensity is significant, and a wavelength range in which high luminous intensity is observed when the silicon oxide film is etched is used as a second wavelength range. Note that, for the second wavelength range, one wavelength range or multiple wavelength ranges may be chosen from among the following wavelength ranges.

For example, example wavelength ranges associated with nitrogen may include one that is associated with: nitrogen molecules (N2); nitrogen molecule positive ions (N2+); nitrogen molecules (N2) and nitrogen hydride molecules (NH); and carbon nitride molecules (CN). Note that one wavelength range or multiple wavelength ranges may be chosen from among the following wavelength ranges.

For example, at least one of a wavelength range from 225 nm to 235 nm (see FIG. 5), a wavelength range from 350 nm to 360 nm (see FIG. 8), or a wavelength range from 375 nm to 390 nm (see FIG. 9) may serve as an example wavelength range associated with nitrogen molecules. To be more specific, the wavelength range associated with nitrogen molecules may be, for example, one ranging from 294 nm to 298 nm, one ranging from 311 nm to 316 nm, one ranging from 352 nm to 359 nm, and one ranging from 380 nm to 392 nm.

The wavelength range associated with nitrogen molecule positive ions is, for example, a wavelength range including 388 nm (see FIG. 9). To be more specific, at least one of a wavelength range from 352 nm to 359 nm or a wavelength range from 380 nm to 389 nm may serve as an example wavelength range associated with nitrogen molecule positive ions.

A wavelength range including 335 nm (see FIG. 7) may serve as an example wavelength range associated with nitrogen molecules and nitrogen hydride molecules. To be more specific, a wavelength range including, for example, at least one of 335 nm or 337 nm may serve as another example wavelength range associated with nitrogen molecules and nitrogen hydride molecules. Note that, for example, a wavelength range that includes 367 nm may serve as an wavelength range associated with nitrogen molecules and nitrogen hydride molecules.

At least one of a wavelength range from 358 nm to 359 nm (see FIG. 8), a wavelength range from 385 nm to 388.5 nm (see FIG. 9), or a wavelength range from 415 nm to 428 nm (see FIG. 10) may serve as a wavelength range associated with carbon nitride molecules. To be more specific, for example, at least one of a wavelength from 385 nm to 388.5 nm or a wavelength range from 415 nm to 421 nm may serve as an example wavelength range associated with carbon nitride molecules.

### (Step S60)

Next, the control part 2 detects etching endpoints. To be more specific, the control part 2 detects the etching endpoint in the first layer L1 when the first luminous intensity acquired in step S40 shows a decrease and the second luminous intensity acquired in step S50 shows an increase. Furthermore, the control part 2 detects the etching endpoint in the second layer L2 when the second luminous intensity acquired in step S50 shows a decrease and the first luminous intensity acquired in step S40 shows an increase.

The control part 2 may combine the first luminous intensity and the second luminous intensity in a linear expression, and, using this expression, determine whether the first luminous intensity shows an increase and the second luminous intensity shows a decrease, or whether the first luminous intensity shows a decrease and the second luminous intensity shows an increase. Furthermore, the control part 2 may determine whether the first luminous intensity shows an increase and the second luminous intensity shows a decrease, or whether the first luminous intensity shows a decrease and the second luminous intensity shows an increase, based on the ratio between the first luminous intensity and the second luminous intensity.

Note that the criteria whereby the control part 2 decides to end etching are not limited to the above examples. For example, the control part 2 may detect an etching endpoint in the first layer L1 when the first luminous intensity acquired in step S40 shows a decrease. Furthermore, the control part 2 may detect an etching endpoint in the first layer L1 when the second luminous intensity acquired in step S50 shows an increase. In summary, the control part 2 may detect an etching endpoint in the first layer L1 either: when the first luminous intensity acquired in step S40 shows a decrease; or when the second luminous intensity acquired in step S50 shows an increase.

Furthermore, for example, the control part 2 may detect an etching endpoint in the second layer L2 when the second luminous intensity acquired in step S50 shows a decrease. Furthermore, the control part 2 may detect an etching endpoint in the second layer L2 when the first luminous intensity acquired in step S40 shows an increase. In summary, the control part 2 may detect an etching endpoint in the second layer L2 either: when the second luminous intensity acquired in step S50 shows a decrease; or when the first luminous intensity acquired in step S40 shows an increase.

Note that, when detecting an etching endpoint, correction may be made based on the luminous intensity in the wavelength range associated with the etchant. To be more specific, the control part 2 may determine a first corrected luminous intensity by dividing the first luminous intensity acquired in step S40 by the reference luminous intensity acquired in step S30.

Furthermore, the control part 2 may determine a second corrected luminous intensity by dividing the second luminous intensity by the reference luminous intensity acquired in step S30 in step S50. Then, the control part 2 may detect an etching endpoint in the first layer when the first corrected luminous intensity shows a decrease and the second corrected luminous intensity shows an increase. Furthermore, the control part 2 may detect an etching endpoint in the second layer when the second corrected luminous intensity shows a decrease and the first corrected luminous intensity shows an increase.

Furthermore, as mentioned earlier, the control part 2 may detect an etching endpoint in the first layer L1 either: when the first corrected luminous intensity shows a decrease; or when the second corrected luminous intensity shows an increase. Furthermore, the control part 2 may detect an etching endpoint in the second layer L2 either: when the second corrected luminous intensity shows a decrease; or when the first corrected luminous intensity shows an increase.

### (Step S70)

Next, the control part 2 determines whether, in step S60, an etching endpoint was detected in the first layer L1 or in the second layer L2. If an etching endpoint was detected in step S60 (“YES” in step S70), the control part 2 proceeds to step S80. If no etching endpoint was detected in step S60 (“NO” in step S70), the control part 2 returns to step S30 and repeats the process.

### (Step S80)

If an etching endpoint was detected in step S60 (“YES” in step S70), the control part 2 stops the etching. To be more specific, the control part 2 stops the supply of processing gas and stops plasma generation.

### (Step S90)

Next, the control part 2 determines whether all layers of the layered film SL have been etched. If all layers of the layered film SL have been etched (“YES” in step S90), the control part 2 proceeds to step S100. If all layers of the layered film SL have not been etched yet, in other words, if the layered film SL still has first layers L1 or second layers L2 that need to be etched (“NO” in step S90), the control part 2 proceeds to step S110.

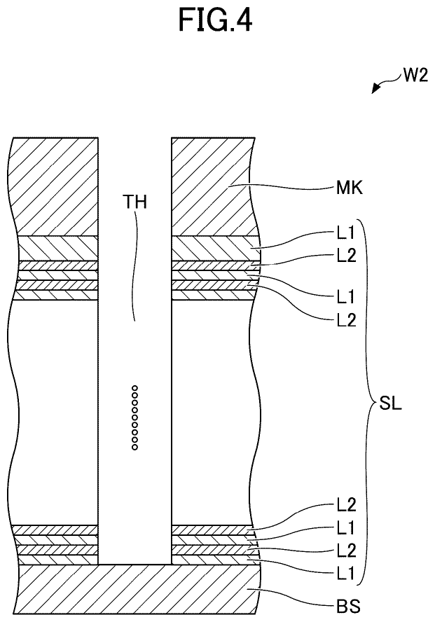

FIG. 4 is a diagram for explaining an overview of a layered film SL having been processed by the plasma processing device 1. A wafer W2, which was originally the W1 and in which all layers constituting the layered film SL have been etched, will be described below with reference to FIG. 4. As shown in FIG. 4, when all the layers constituting the layered film SL have been etched (“YES” in step S90), a through-hole TH that penetrates all the way to the substrate BS is formed, as in the wafer W2.

### (Step S100)

If all the layers constituting the layered film SL have been etched (“YES” in step S90), the control part 2 carries out a post-processing step. To be more specific, the control part 2 controls the processed wafer to be unloaded to outside the plasma processing device 1.

### (Step S110)

If all layers of the layered film SL have not been etched yet, in other words, if the layered film SL still has first layers L1 or second layers L2 that need to be etched (“NO” in step S90), the control part 2 changes the processing conditions to etch the next layer. For example, if all the first layers L1 have been etched, the processing conditions are changed such that the remaining second layers L2 are going to be etched. On the other hand, if all the second layers L2 have been etched, the processing conditions are changed such that the remaining first layers L1 are going to be etched.

Note that the wavelength ranges described above are only examples. For example, a wavelength range associated with oxygen or a wavelength range associated with nitrogen may be chosen as appropriate from among the wavelength ranges shown in FIG. 5 to FIG. 12.

### SUMMARY

The plasma processing device of the present embodiment enables efficient endpoint detection when etching a layered film formed with first layers and second layers that are stacked alternately on top one another. Furthermore, when etching a layered film formed with first layers and second layers that are stacked alternately on top of one another, the plasma processing device of the present embodiment can carry out the same endpoint detection process for each first layer and second layer. In addition, the plasma processing device of the present embodiment can prevent or substantially prevent changes of processing conditions upon etching of the first layers and etching of the second layers from having an impact by using luminous intensities taken from reference wavelength ranges.

Furthermore, the plasma processing device of the present embodiment can detect endpoints when etching a layered film formed with first layers and second layers that are stacked alternately on top of one another, making it possible to switch the process to carry out such that optimal processing conditions are applied to the first layers and the second layers.

The plasma processing device according to the present embodiment should be considered to be illustrative in all respects, and not restrictive. The above-described embodiment can be modified and improved in various ways without departing from the spirit and scope of the accompanying claims. Matters described in the embodiment and examples disclosed herein may be structured differently, configured differently, or combined together as long as inconsistencies do not arise.

What is claimed is:

1. A plasma processing device, comprising:
a spectrometer configured to measure luminous intensity while plasma processing is in progress; and
control circuitry configured to control etching endpoint detection based on measurement results gained on the spectrometer,
wherein, when a layered film formed with first layers and second layers is etched using plasma, the first layers and the second layers being stacked alternately on top of one another and forming the layered film together, the first layers containing silicon and oxygen and the second layers containing silicon and nitrogen, the control circuitry configured to:
(a) acquire a first luminous intensity from the spectrometer while plasma processing is in progress, the first luminous intensity being taken from a first wavelength range that is associated with the oxygen;
(b) acquire a second luminous intensity from the spectrometer while plasma processing is in progress, the second luminous intensity being taken from a second wavelength range that is different from the first wavelength range and associated with the nitrogen; and
(c) detect an etching endpoint in one of the first layers when the first luminous intensity shows a decrease and the second luminous intensity shows an increase, and detect an etching endpoint in one of the second layers when the second luminous intensity shows a decrease and the first luminous intensity shows an increase.

2. The plasma processing device according to claim 1,
wherein the control circuitry is further configured to:
(d) acquire a reference luminous intensity from the spectrometer while plasma processing is in progress, the reference luminous intensity being taken from a reference wavelength range that is associated with an etchant, and
wherein, in (c), the control circuitry is configured to:
(c-1) determine a first corrected luminous intensity by dividing the first luminous intensity by the reference luminous intensity;
(c-2) determine a second corrected luminous intensity by dividing the second luminous intensity by the reference luminous intensity; and
(c-3) detect the etching endpoint in the one of the first layers when the first corrected luminous intensity shows a decrease and the second corrected luminous intensity shows an increase, and detect the etching endpoint in the one of the second layers when the second corrected luminous intensity shows a decrease and the first corrected luminous intensity shows an increase.

3. The plasma processing device according to claim 1, wherein the first wavelength range includes at least one of:
a wavelength range associated with oxygen atoms; or
a wavelength range associated with hydroxyl radicals.

4. The plasma processing device according to claim 3, wherein the wavelength range associated with oxygen atoms includes a wavelength of at least one of 777.2 nm, 777.4 nm, 794.8 nm, or 844.6 nm.

5. The plasma processing device according to claim 3, wherein the wavelength range associated with the hydroxyl radicals includes a wavelength of at least one of 309 nm or 324 nm.

6. The plasma processing device according to claim 1, wherein the second wavelength range includes at least one of:
a wavelength range associated with nitrogen molecules;
a wavelength range associated with nitrogen molecule positive ions;
a wavelength range associated with nitrogen molecules and nitrogen hydride molecules; or
a wavelength range associated with carbon nitride molecules.

7. The plasma processing device according to claim 6, wherein the wavelength range associated with the nitrogen molecules includes at least one of:
a wavelength range from 294 nm to 298 nm;
a wavelength range from 311 nm to 316 nm;
a wavelength range from 352 nm to 359 nm; or
a wavelength range from 380 nm to 392 nm.

8. The plasma processing device according to claim 6, wherein the wavelength range associated with the nitrogen molecule positive ions includes at least one of:
a wavelength range from 352 nm to 359 nm; or
a wavelength range from 380 nm to 389 nm.

9. The plasma processing device according to claim 6, wherein the wavelength range associated with the nitrogen molecules and nitrogen hydride molecules includes a wavelength including at least one of 335 nm or 337 nm.

10. The plasma processing device according to claim 6, wherein the wavelength range associated with the carbon nitride molecules includes at least one of:
a wavelength range from 385 nm to 388.5 nm; or
a wavelength range from 415 nm to 428 nm.

11. A method of detecting, comprising:
(a) etching, by plasma processing, a layered film formed with first layers and second layers, the first layers and the second layers being stacked alternately on top of one another and forming the layered film together, the first layers containing silicon and oxygen and the second layers containing silicon and nitrogen, and acquiring a first luminous intensity while the plasma processing is in progress, the first luminous intensity being taken from a first wavelength range that is associated with the oxygen;
(b) acquiring a second luminous intensity while plasma processing is in progress, the second luminous intensity being taken from a second wavelength range that is different from the first wavelength range and associated with the nitrogen; and
(c) detecting an etching endpoint in one of the first layers when the first luminous intensity shows a decrease and the second luminous intensity shows an increase, and detecting an etching endpoint in one of the second layers when the second luminous intensity shows a decrease and the first luminous intensity shows an increase.

12. The method according to claim 11,
wherein the method further comprises:
(d) acquiring a luminous reference intensity while plasma processing is in progress, the reference luminous intensity being taken from a reference wavelength range that is associated with an etchant, and
wherein (c) in the method includes:
(c-1) determining a first corrected luminous intensity by dividing the first luminous intensity by the reference luminous intensity;
(c-2) determining a second corrected luminous intensity by dividing the second luminous intensity by the reference luminous intensity; and
(c-3) detecting the etching endpoint in the one of the first layers when the first corrected luminous intensity shows a decrease and the second corrected luminous intensity shows an increase, and detecting the etching endpoint in the one of the second layers when the second corrected luminous intensity shows a decrease and the first corrected luminous intensity shows an increase.

13. The method according to claim 11, wherein the first wavelength range includes at least one of:
a wavelength range associated with oxygen atoms; or
a wavelength range associated with hydroxyl radicals.

14. The method according to claim 13, wherein the wavelength range associated with the oxygen atoms includes a wavelength of at least one of 777.2 nm, 777.4 nm, 794.8 nm, or 844.6 nm.

15. The method according to claim 11, wherein the second wavelength range includes at least one of:
a wavelength range associated with nitrogen molecules;
a wavelength range associated with nitrogen molecule positive ions;
a wavelength range associated with nitrogen molecules and nitrogen hydride molecules; or
a wavelength range associated with carbon nitride molecules.

16. The method according to claim 15, wherein the wavelength range associated with the nitrogen molecules includes at least one of:
a wavelength range from 294 nm to 298 nm;
a wavelength range from 311 nm to 316 nm;
a wavelength range from 352 nm to 359 nm; or
a wavelength range from 380 nm to 392 nm.

17. The method according to claim 16, wherein the wavelength range associated with the nitrogen molecule positive ions includes at least one of:
a wavelength range from 352 nm to 359 nm; or
a wavelength range from 380 nm to 389 nm.

18. The method according to claim 16, wherein the wavelength range associated with the nitrogen molecules and nitrogen hydride molecules includes a wavelength including at least one of 335 nm or 337 nm.

19. The method according to claim 16, wherein the wavelength range associated with the carbon nitride molecules includes at least one of:
a wavelength range from 385 nm to 388.5 nm; or
a wavelength range from 415 nm to 428 nm.

20. A plasma processing device comprising:
a spectrometer configured to measure luminous intensity while plasma processing is in progress; and
control circuitry configured to control etching endpoint detection based on measurement results gained on the spectrometer,
wherein, when a layered film formed with first layers and second layers is etched using plasma, the first layers and the second layers being stacked alternately on top of one another and forming the layered film together, the first layers containing silicon and oxygen and the second layers containing silicon and nitrogen, the control circuitry is configured to:
(a) acquire a first luminous intensity from the spectrometer while plasma processing is in progress, the first luminous intensity being taken from a first wavelength range that is associated with the oxygen;
(b) acquire a second luminous intensity from the spectrometer while plasma processing is in progress, the second luminous intensity being taken from a second wavelength range that is different from the first wavelength range and associated with the nitrogen; and
(c) detect an etching endpoint in one of the layers when first the first luminous intensity shows a decrease or the second luminous intensity shows an increase, or both, and detect an etching endpoint in one of the second layers when the second luminous intensity shows a decrease or the first luminous intensity shows an increase, or both.
